(19) United States
(12) Patent Application Publication
(10) Pub. No.: US 2016/0226009 A1
(43) Pub. Date: Aug. 4, 2016

(54) THIN FILM SOLAR CELL, SEMICONDUCTOR THIN FILM AND COATING LIQUID FOR FORMING SEMICONDUCTOR

(71) Applicant: SEKISUI CHEMICAL CO., LTD., Osaka (JP)

(72) Inventors: Mayumi HORIKI, Osaka (JP); Kazushi ITO, Osaka (JP); Akinobu HAYAKAWA, Osaka (JP); Shunji OHARA, Osaka (JP)

(73) Assignee: SEKISUI CHEMICAL CO., LTD., Osaka (JP)

(21) Appl. No.: 15/021,741

(22) PCT Filed: Sep. 24, 2014
(86) PCT No.: PCT/JP2014/075293

§ 371 Date: Mar. 14, 2016

(30) Foreign Application Priority Data
Sep. 25, 2013 (JP) 2013-198851
Apr. 15, 2014 (JP) 2014-083660

(51) Int. Cl. H01L 51/42; H01L 51/44

(52) U.S. Cl. CPC H01L 51/422; H01L 51/447; H01L 51/442; H01L 2031/0344

(57) ABSTRACT

The present invention provides a thin film solar cell which can exhibit high photoelectric conversion efficiency. The present invention aims to provide a semiconductor thin film intended to be used in the thin film solar cell and to a coating liquid for forming a semiconductor which can facilitate large-area production of the thin film solar cell to improve production stability. The present invention relates to a thin film solar cell including a photoelectric conversion layer. The photoelectric conversion layer includes a portion that includes a sulfide of a group 15 element of the periodic table and/or a selenide of a group 15 element of the periodic table and a compound containing at least one element selected from the group consisting of a rare earth element, titanium, and zinc.

### TECHNICAL FIELD

The present invention relates to a thin film solar cell that can exhibit high photoelectric conversion efficiency. The present invention also relates to a semiconductor thin film intended to be used in the thin film solar cell; and a coating liquid for forming a semiconductor which can facilitate large-area production of the thin film solar cell and can improve production stability.

### BACKGROUND ART

Photoelectric conversion elements have been developed which are composed of a laminate of several semiconductor thin films and electrodes on both sides of the laminate. Replacement of such a laminate with a composite film containing several semiconductors has also been studied. In such photoelectric conversion elements, each semiconductor acts as a P-type or N-type semiconductor in which photocarriers (electron-hole pairs) are formed upon excitation with light. The electrons and holes move through the N-type semiconductor and P-type semiconductor, respectively, to create an electric field.

Semiconductors which have gained attention for use in photoelectric conversion elements include sulfide or selenide semiconductors such as antimony sulfide (Sb₂S₃), bismuth sulfide (Bi₂S₃), and antimony selenide. Sulfide or selenide semiconductors such as antimony sulfide, bismuth sulfide, and antimony selenide show promise as a photoelectric conversion material as they have a band gap of 1.0 to 2.5 eV and exhibit high light absorption properties in the visible light region. The sulfide or selenide semiconductors such as antimony sulfide, bismuth sulfide, and antimony selenide are also expected to serve as a visible-light-responsive photocatalyst material. Furthermore, they have been eagerly studied for use in infrared radiation sensors because of their high light transmission in the infrared region. Additionally, they have drawn attention as a photoconductive material as they exhibit changes in the electric conductivity upon irradiation with light.

However, thin film solar cells produced using sulfide or selenide semiconductors have a lower photoelectric conversion efficiency than other photoelectric conversion elements, such as silicon solar cells or organic thin film solar cells.

The thin film of the sulfide or selenide semiconductor has been produced by, for example, a vacuum evaporation method, a sputtering method, a chemical vapor deposition (CVD) method, or an electrochemical deposition method (for example, see Non-Patent Literatures 1 and 2). Such methods as a vacuum evaporation method or a sputtering method need expensive apparatus, leading to cost disadvantages. In addition, these methods are difficult to use for forming large-area films. The electrochemical deposition method is applicable only to film formation on conductive substrates, although it requires no vacuum equipment and allows film formation at normal temperature.

### CITATION LIST

### Non Patent Literature

Non-Patent Literature 1: Matthieu Y. Versavel and Joel A. Haber, Thin Solid Films, 515(18), 7171-7176 (2007)
Non-Patent Literature 2: N. S. Yesugade, et al., Thin Solid Films, 263(2), 145-149 (1995)

### SUMMARY OF INVENTION

### Technical Problem

One object of the present invention is to provide a thin film solar cell that can exhibit high photoelectric conversion efficiency. Another object of the present invention is to provide a semiconductor thin film intended to be used in the thin film solar cell and a coating liquid for forming a semiconductor which can facilitate large-area production of the thin film solar cell and can improve production stability.

### Solution to Problem

The present invention relates to a thin film solar cell including a photoelectric conversion layer. The photoelectric conversion layer includes a portion that includes a sulfide of a group 15 element of the periodic table and/or a selenide of a group 15 element of the periodic table and a compound containing at least one element selected from the group consisting of a rare earth element, titanium, and zinc.

The following will describe the present invention in detail.

The present inventors have found out that improved photoelectric conversion efficiency can be achieved by a thin film solar cell in which the photoelectric conversion layer includes a portion that includes a sulfide of a group 15 element of the periodic table and/or a selenide of a group 15 element of the periodic table and a compound containing at least one element selected from the group consisting of a rare earth element, titanium, and zinc.

The present inventors also have found out that the following. Use of a coating liquid for forming a semiconductor which includes a compound containing a group 15 element of the periodic table, a sulfur-containing compound and/or a selenium-containing compound, and a compound containing at least one element selected from the group consisting of a rare earth element, titanium, and zinc enables the employment of a printing method in the production of the thin film solar cell. This facilitates large-area production of thin film solar cells with high photoelectric conversion efficiency. The present inventors also have found that formation of a complex of the compound containing a group 15 element of the periodic table with the sulfur-containing compound and/or the selenium-containing compound can improve the production stability of the thin film solar cell. The inventors thus completed the present invention.

The thin film solar cell of the present invention includes a photoelectric conversion layer.

The photoelectric conversion layer includes a portion (hereinafter, also referred to as “sulfide and/or selenide semiconductor portion”) that includes a sulfide of a group 15 element of the periodic table and/or a selenide of a group 15 element of the periodic table and a compound containing at least one element selected from the group consisting of a rare earth element, titanium, and zinc.

The sulfide and/or selenide semiconductor portion includes a sulfide of a group 15 element of the periodic table and/or a selenide of a group 15 element of the periodic table. Due to high durability of the sulfide of a group 15 element of the periodic table and/or the selenide of a group 15 element of the periodic table, the sulfide and/or selenide semiconductor portion with a sulfide of a group 15 element of the periodic table and/or a selenide of a group 15 element of the periodic table imparts excellent durability to the thin film solar cell of the present invention.

The sulfide of a group 15 element of the periodic table and/or the selenide of a group 15 element of the periodic table are/is not limited, and may be used singly, or two or more thereof may be used in combination. A composite sulfide or composite selenide containing two or more elements of group 15 of the periodic table in one molecule may be used. In particular, antimony sulfide, bismuth sulfide, and antimony selenide are preferred. Antimony sulfide and antimony selenide are more preferred.

The antimony sulfide or antimony selenide is highly compatible with organic semiconductors and/or inorganic semiconductors (described later) in terms of the energy level, and also has higher absorption of visible light than conventionally used semiconductors, such as zinc oxide or titanium oxide. If the sulfide and/or selenide semiconductor portion includes antimony sulfide or antimony selenide, the thin film solar cell can have significantly high charge separation efficiency, increasing photoelectric conversion efficiency.

Additionally, if the sulfide and/or selenide semiconductor portion includes antimony sulfide or antimony selenide, the thin film solar cell can have high production stability (reproducibility of photoelectric conversion efficiency) than if the portion includes sulfides or selenides of other group 15 elements of the periodic table. The reason of this is not clear, but is presumably that antimony metal is less likely to precipitate in antimony sulfide or antimony selenide. Among the group 15 elements of the periodic table, bismuth, for example, has an unstable crystal structure. Bismuth metal thus easily precipitates in bismuth sulfide, which presumably tends to reduce the production stability (reproducibility of photoelectric conversion efficiency) of the thin film solar cell.

The production stability (reproducibility of photoelectric conversion efficiency) herein means the reproducibility of the photoelectric conversion efficiency between multiple thin film solar cells produced by the same method.

The sulfide and/or selenide semiconductor portion includes a compound (hereinafter, also referred to as “compound containing a rare earth element and/or other elements”) that contains at least one element selected from the group consisting of a rare earth element, titanium, and zinc. The sulfide and/or selenide semiconductor portion includes the compound containing a rare earth element and/or other elements in addition to the sulfide of a group 15 element of the periodic table and/or the selenide of a group 15 element of the periodic table, and thus the thin film solar cell of the present invention can exhibit high photoelectric conversion efficiency. Additionally, the use of the compound containing a rare earth element and/or other elements can suppress changes in the coating liquid for forming a semiconductor (described later) over time as compared with the use of no compound containing a rare earth element and/or other elements. As a result, the storage stability of the coating liquid can be improved.

The rare earth element includes yttrium (Y), scandium (Sc), and elements commonly referred to as lanthanoid.

Specific examples of the rare earth element other than yttrium (Y) and scandium (Sc) include lanthanoids such as lanthanum (La), cerium (Ce), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu). These rare earth elements may be used alone, or in combination of two or more thereof. In particular, yttrium (Y), scandium (Sc), lanthanum (La), neodymium (Nd), samarium (Sm), gadolinium (Gd), terbium (Tb), dysprosium (Dy), holmium (Ho), erbium (Er), thulium (Tm), and lutetium (Lu) are preferred because they are stable in the trivalent state as antimony (Sb) is, and are not radioisotopes.

The compound containing a rare earth element and/or other elements may be any compound that contains at least one element selected from the group consisting of a rare earth element, titanium, and zinc. It may be a titanium-containing compound (e.g., a titanium alkoxide such as titanium isopropoxide) or a zinc-containing compound (e.g., zinc chloride). Preferably, it is a compound containing a rare earth element (e.g., a chloride or nitrate of a rare earth element). If the sulfide and/or selenide semiconductor portion includes a compound containing a rare earth element, the sulfide and/or selenide semiconductor portion has a reduced interface resistance. In particular, compounds containing a rare earth element and zinc are more preferred. Compounds containing lanthanum and zinc and compounds containing lutetium and zinc are particularly preferred.

The lower limit of the amount of the compound containing a rare earth element and/or other elements in the sulfide and/or selenide semiconductor portion is preferably 1 mol %, whereas the upper limit thereof is 50 mol %, in 100 mol % of the total amount of the sulfide of a group 15 element of the periodic table and/or the selenide of a group 15 element of the periodic table and the compound containing a rare earth element and/or other elements. If the amount is 1 mol % or more, the effects of the addition of the compound containing a rare earth element and/or other elements can be sufficiently exerted, increasing the photoelectric conversion efficiency. If the amount is 50 mol % or less, the sulfide and/or selenide semiconductor portion can maintain its crystal structure, increasing photoelectric conversion efficiency. The lower limit of the amount is more preferably 2 mol %, whereas the upper limit thereof is more preferably 35 mol %.

The amount of the compound containing a rare earth element and/or other elements in the sulfide and/or selenide semiconductor portion can be measured with, for example, an ICP emission spectrometer (ICPS-7500, available from Shimadzu).

The sulfide and/or selenide semiconductor portion is preferably a crystalline semiconductor. If the sulfide and/or selenide semiconductor portion is a crystalline semiconductor, high electron mobility is obtained, which improves the photoelectric conversion efficiency.

The crystalline semiconductor refers to a semiconductor whose scattering peaks can be detected by X-ray diffraction measurement or other techniques.

The degree of crystallinity may be employed as an index of the crystallinity of the sulfide and/or selenide semiconductor portion. The lower limit of the degree of crystallinity of the sulfide and/or selenide semiconductor portion is preferably 30%. If the degree of crystallinity is 30% or more, the electron mobility is enhanced, improving the photoelectric conversion efficiency. The lower limit of the degree of crystallinity is more preferably 50%, still more preferably 70%.

The degree of crystallinity can be determined as follows: scattering peaks derived from a crystalline fraction and halo derived from an amorphous fraction detected by X-ray diffraction measurement or other techniques are separated by fitting; integrated intensities thereof are determined; and the proportion of the crystalline fraction in the entire sulfide and/or selenide semiconductor portion is calculated.

In order to increase the degree of crystallinity of the sulfide and/or the selenide of the sulfide and/or selenide semiconductor portion, the sulfide and/or selenide semiconductor portion may be subjected to, for example, burning, exposure to strong light such as laser or flash lamp, exposure to excimer light, or exposure to plasma. Exposure to strong light or exposure to plasma, for example, is especially preferable as such a technique enables to suppress oxidation of the sulfide and/or selenide semiconductor portion.

The photoelectric conversion layer preferably further includes a portion that includes an organic semiconductor and/or an inorganic semiconductor adjacent to the sulfide and/or selenide semiconductor portion. In particular, the photoelectric conversion layer preferably includes a portion (hereinafter, also referred to as “organic semiconductor portion”) that contains an organic semiconductor because it allows the thin film solar cell to be excellent in production stability, shock resistance, and flexibility.

The organic semiconductor is not limited. Examples thereof include compounds that have a thiophene backbone such as poly(3-alkylthiophene). Other examples thereof include conductive polymers having a polyparaphenylene vinylene backbone, a polyvinyl carbazole backbone, a polyaniline backbone, or a polyacetylene backbone. Other examples further include compounds having a phthalocyanine skeleton, a naphthalocyanine skeleton, a pentacene skeleton, or a porphyrin skeleton such as a benzoporphyrin skeleton. In particular, compounds having a thiophene skeleton, a phthalocyanine skeleton, a naphthalocyanine skeleton, or a benzoporphyrin skeleton are preferred because they have relatively high durability.

It is also preferable that the organic semiconductor is a donor-acceptor type organic semiconductor because it can absorb light in a long wavelength region. In particular, the organic semiconductor is more preferably a donor-acceptor compound having a thiophene backbone. Among donor-acceptor compounds having a thiophene backbone, thiophene-diketopyrrolopyrrole polymers are particularly preferable from the viewpoint of light absorption wavelengths.

If the photoelectric conversion layer includes the sulfide and/or selenide semiconductor portion and the organic semiconductor portion, it is presumed that the sulfide and/or selenide semiconductor portion mainly acts as an N-type semiconductor and the organic semiconductor portion mainly acts as a P-type semiconductor. Photocarriers (electron-hole pairs) are formed in the P-type semiconductor or the N-type semiconductor upon excitation with light, and electrons and holes move through the N-type semiconductor and the P-type semiconductor, respectively, to create electric field. The sulfide and/or selenide semiconductor portion may partially act as a P-type semiconductor, and the organic semiconductor portion may partially act as an N-type semiconductor.

If the photoelectric conversion layer includes the sulfide and/or selenide semiconductor portion and the organic semiconductor portion, the photoelectric conversion layer may be a laminate including the sulfide and/or selenide semiconductor portion in the form of a thin film and the organic semiconductor portion in the form of a thin film. Alternatively, the photoelectric conversion layer may be a composite film including a composite of the sulfide and/or selenide semiconductor portion and the organic semiconductor portion. The composite film is preferred as it can improve charge separation efficiency of the organic semiconductor portion. The laminate is preferred as it can be produced by a simple method.

The inorganic semiconductor is not limited. Examples thereof include molybdenum oxide, molybdenum sulfide, tin sulfide, nickel oxide, copper oxide, copper sulfide, iron sulfide, copper-indium-selenium compound (CuInSe₂), copper-indium sulfide (CuInS₂), and copper-zinc-tin sulfide (Cu₂ZnSnS₄). In particular, molybdenum oxide, molybdenum sulfide, and tin sulfide are preferred because they have higher stability.

The inorganic semiconductor may contain other elements in addition to the inorganic semiconductor as a main component described above, to the extent that they do not impair the effects of the present invention. Such other elements are not limited. Examples thereof include copper, zinc, silver, indium, cadmium, antimony, bismuth, and gallium. These elements may be used alone, or in combination of two or more thereof. In particular, copper, indium, gallium, and zinc are preferred because they enhance the electron mobility.

The surfaces of the photoelectric conversion layer preferably each have an arithmetic average roughness Ra measured in accordance with JIS B 0601-2001 of 5 nm or more. If the photoelectric conversion layer has rough surfaces with an arithmetic average roughness Ra of 5 nm or more, the thin film solar cell to be obtained has further improved photoelectric conversion efficiency.

Such a photoelectric conversion layer with rough surfaces is difficult to produce with conventional methods such as a vacuum evaporation method or a sputtering method. In the present invention, the photoelectric conversion layer can be formed by a printing method using a coating liquid for forming a semiconductor which includes a compound containing a group 15 element of the periodic table, a sulfur-containing compound and/or a selenium-containing compound, and a compound containing at least one element selected from the group consisting of a rare earth element, titanium, and zinc. In this case, the photoelectric conversion layer with an arithmetic average roughness Ra of 5 nm or more can be easily formed.

The upper limit of the arithmetic average roughness Ra of the photoelectric conversion layer is not limited, but is preferably 1 μm or less from the viewpoint of the efficiency of hole transport.

Herein, the surfaces of the photoelectric conversion layer refer to both the portion corresponding to the interface between the photoelectric conversion layer and the hole transport layer and the portion corresponding to the interface between the photoelectric conversion layer and the electron transport layer.

The thin film solar cell of the present invention preferably includes the photoelectric conversion layer between a pair of electrodes.

The materials of the electrodes are not limited, and may be conventionally known materials. Examples of the materials of the anode include metals such as gold, conductive transparent materials such as CuI, indium tin oxide (ITO), SnO₂, AZO, IZO, or GZO, and conductive transparent polymers. Examples of materials of the cathode include sodium, sodium-potassium alloys, lithium, magnesium, aluminum, magnesium-silver mixtures, magnesium-indium mixtures, aluminum-lithium alloys, Al/Al₂O₃ mixtures, Al/LiF mixtures, and fluorine-doped tin oxide (FTO). These materials may be used alone, or in combination of two or more thereof.

The thin film solar cell of the present invention may further include a substrate, a hole transport layer, an electron transport layer, or other components. The substrate is not limited, and may be, for example, a transparent glass substrate such as a soda-lime glass or alkali-free glass substrate, a ceramic substrate, or a transparent plastic substrate.

The materials of the hole transport layer are not limited. Examples of the materials include P-type conductive polymers, P-type low molecular weight organic semiconductors, P-type metal oxides, P-type metal sulfides, and surfactants. Specific examples thereof include polystyrene sulfonate-doped polyethylene dioxythiophene, carboxyl group-containing polythiophene, phthalocyanine, porphyrin, molybdenum oxide, vanadium oxide, tungsten oxide, nickel oxide, copper oxide, tin oxide, molybdenum sulfide, tungsten sulfide, copper sulfide, tin sulfide or the like, fluoro group-containing phosphonic acid, and carbonyl group-containing phosphonic acid.

The materials of the electron transport layer are not limited. Examples of the materials include N-type conductive polymers, N-type low molecular weight organic semiconductors, N-type metal oxides, N-type metal sulfides, alkali metal halides, alkali metals, and surfactants. Specific examples thereof include cyano group-containing polyphenylene vinylene, boron-containing polymers, bathocuproine, bathophenanthroline, hydroxy quinolinato aluminum, oxadiazol compounds, benzoimidazole compounds, naphthalene tetracarboxylic acid compounds, perylene derivatives, phosphine oxide compounds, phosphine sulfide compounds, fluoro group-containing phthalocyanine, titanium oxide, zinc oxide, indium oxide, tin oxide, gallium oxide, tin sulfide, indium sulfide, and zinc sulfide.

In particular, the thin film solar cell of the present invention preferably includes a photoelectric conversion layer that is a laminate including the sulfide and/or selenide semiconductor portion in the form of a thin film and the organic semiconductor portion in the form of a thin film between a pair of electrodes, and preferably further includes an electron transport layer between one of the electrodes and the sulfide and/or selenide semiconductor portion. The thin film solar cell of the present invention more preferably further includes a hole transport layer between the other electrode and the organic semiconductor portion.

FIG. 1 schematically shows one exemplary embodiment of the thin film solar cell of the present invention which includes a photoelectric conversion layer that is a laminate including a sulfide and/or selenide semiconductor portion in the form of a thin film and an organic semiconductor portion in the form of a thin film. In a thin film solar cell 1 shown in FIG. 1, a substrate 2, an electrode (anode) 3, an organic semiconductor potion 4 in the form of a thin film, a sulfide and/or selenide semiconductor portion 5 in the form of a thin film, an electron transport layer 6, and a transparent electrode (cathode) 7 are laminated in the stated order.

The lower limit of the thickness of the sulfide and/or selenide semiconductor portion in the form of a thin film is preferably 5 nm, whereas the upper limit thereof is preferably 5000 nm. If the thickness is 5 nm or more, the portion can sufficiently absorb light, thus increasing the photoelectric conversion efficiency. If the thickness is 5000 nm or less, the generation of regions where charge separation does not occur can be suppressed, thus improving the photoelectric conversion efficiency. The lower limit of the thickness is more preferably 10 nm, and the upper limit is more preferably 1000 nm. The lower limit is still more preferably 20 nm, and the upper limit is still more preferably 500 nm.

The lower limit of the thickness of the organic semiconductor portion in the form of a thin film is preferably 5 nm, whereas the upper limit thereof is preferably 5000 nm. If the thickness is 5 nm or more, the portion can sufficiently absorb light, thus increasing the photoelectric conversion efficiency. If the thickness is 5000 nm or less, the generation of regions where charge separation does not occur can be suppressed, thus improving the photoelectric conversion efficiency. The lower limit of the thickness is more preferably 10 nm, and the upper limit is more preferably 2000 nm. The lower limit is still more preferably 20 nm, and the upper limit is still more preferably 1000 nm.

The thin film solar cell of the present invention preferably includes, between a pair of electrodes, a photoelectric conversion layer that is a composite film including a composite of the sulfide and/or selenide semiconductor portion and the organic semiconductor portion, and preferably further includes an electron transport layer between one of the electrodes and the photoelectric conversion layer. The thin film solar cell preferably further includes a hole transport layer between the other electrode and the photoelectric conversion layer.

FIG. 2 schematically shows one exemplary embodiment of the thin film solar cell of the present invention which includes a photoelectric conversion layer that is a composite film including a composite of the sulfide and/or selenide semiconductor portion and the organic semiconductor portion. In a thin film solar cell 8 shown in FIG. 2, a substrate 9, an electrode (anode) 10, a hole transport layer 11, a composite film 14 of an organic semiconductor portion 12 and a sulfide and/or selenide semiconductor portion 13, an electron transport layer 15, and a transparent electrode (cathode) 16 are laminated in the stated order.

The lower limit of the thickness of the composite film is preferably 30 nm, whereas the upper limit thereof is preferably 3000 nm. If the thickness is 30 nm or more, the film can sufficiently absorb light, thus increasing the photoelectric conversion efficiency. If the thickness is 3000 nm or less, the electrical charge easily can reach the electrodes, thus increasing the photoelectric conversion efficiency. The lower limit of the thickness is more preferably 40 nm, and the upper limit is more preferably 2000 nm. The lower limit is still more preferably 50 nm, and the upper limit is still more preferably 1000 nm.

In the composite film, the ratio between the sulfide and/or selenide semiconductor portion and the organic semiconductor portion is very important. The ratio between the sulfide/selenide semiconductor portion and the organic semiconductor portion is preferably 1:9 to 9:1 (volume ratio). If the ratio is within the above range, holes or electrons easily reach the electrodes, thus improving the photoelectric conversion efficiency. The ratio is more preferably 2:8 to 8:2 (volume ratio).

The lower limit of the thickness of the hole transport layer is preferably 1 nm, whereas the upper limit thereof is preferably 2000 nm. If the thickness is 1 nm or more, the hole transport layer can sufficiently block electrons. If the thickness is 2000 nm or less, the hole transport layer is less likely to create resistance to hole transport, thus increasing the photoelectric conversion efficiency. The lower limit of the thickness is more preferably 3 nm, and the upper limit is more preferably 1000 nm. The lower limit is still more preferably 5 nm, the upper limit is still more preferably 500 nm.

The lower limit of the thickness of the electron transport layer is preferably 1 nm, whereas the upper limit thereof is preferably 2000 nm. If the thickness is 1 nm or more, the electron transport layer can sufficiently block holes. If the thickness is 2000 nm or less, the electron transport layer is less likely to create resistance to electron transport, thus increasing the photoelectric conversion efficiency. The lower limit of the thickness is more preferably 3 nm, and the upper limit is more preferably 1000 nm. The lower limit is still more preferably 5 nm, the upper limit is still more preferably 500 nm.

The thin film solar cell of the present invention may be produced by any method. For example, it may be produced by forming an electrode (anode) on a substrate, subsequently forming a photoelectric conversion layer on the electrode (anode), and then forming an electrode (cathode) on the photoelectric conversion layer. Alternatively, an electrode (cathode) may be first formed on a substrate, and then a photoelectric conversion layer and an electrode (anode) may be formed in the stated order.

The photoelectric conversion layer may be formed by any method. It may be formed by, for example, a vacuum evaporation method, a sputtering method, a chemical vapor deposition (CVD) method, or an electrochemical deposition method. A preferred method is a printing method that uses a coating liquid for forming a semiconductor which includes a compound containing a group 15 element of the periodic table, a sulfur-containing compound and/or a selenium-containing compound, and a compound containing a rare earth element and/or other elements. The use of methods such as vacuum evaporation, sputtering, chemical vapor deposition (CVD), and electrochemical deposition methods makes it difficult to control the amount and distribution of dopant (i.e., the compound containing a rare earth element and/or other elements). In the case of forming the photoelectric conversion layer by the printing method, the amount and distribution of dopant can be easily controlled, thus increasing the photoelectric conversion efficiency.

Furthermore, in the case of forming the photoelectric conversion layer by the printing method, the surfaces of the resulting photoelectric conversion layer can have an arithmetic average roughness Ra of 5 nm or more.

In addition, the formation of the photoelectric conversion layer by a vacuum evaporation method or other conventional methods has the issue of film thickness dependence. Specifically, the photoelectric conversion efficiency decreases if the film thickness of the photoelectric conversion layer increases during the production process. In the case of forming the photoelectric conversion layer by the printing method, the photoelectric conversion layer to be obtained can have a reduced film thickness dependence. In other words, the employment of the printing method can suppress the decrease in the photoelectric conversion efficiency of the thin film solar cell to be obtained even if the film thickness of the photoelectric conversion layer increases during the production process. The reason of this is considered as follows. Since the printing method allows the surfaces of the layer to have an arithmetic average roughness Ra of 5 nm or more, the distance from the interface between the photoelectric conversion layer and electron transport layer to the interface between the photoelectric conversion layer and hole transport layer is less likely to be large even if the film thickness of the photoelectric conversion layer increases. As a result, the properties that depend on the film thickness are more stable.

More specifically, the photoelectric conversion layer can be formed by the printing method as follows. For example, for a photoelectric conversion layer that is a laminate including the sulfide and/or selenide semiconductor portion in the form of a thin film and the organic semiconductor portion in the form of a thin film, it is preferred that a sulfide and/or selenide semiconductor portion in the form of a thin film is formed by a printing method such as a spin coating method using the coating liquid for forming a semiconductor mentioned above, and an organic semiconductor portion in the form of a thin film is formed on the sulfide and/or selenide semiconductor portion in the form of a thin film by a printing method such as a spin coating method. Conversely, the sulfide and/or selenide semiconductor portion in the form of a thin film may be formed on the organic semiconductor portion in the form of a thin film.

For a photoelectric conversion layer that is a composite film including a composite of the sulfide and/or selenide semiconductor portion and the organic semiconductor portion, for example, it is preferred that the composite film is formed by a printing method such as a spin coating method using a mixture containing the coating liquid for forming a semiconductor and an organic semiconductor.

The present invention also encompasses a coating liquid for forming a semiconductor which includes a compound containing a group 15 element of the periodic table, a sulfur-containing compound and/or a selenium-containing compound, and a compound containing a rare earth element and/or other elements.

The use of the coating liquid for forming a semiconductor of the present invention enables formation of the above-described sulfide and/or selenide semiconductor portion of the thin film solar cell of the present invention. The use of the coating liquid for forming a semiconductor of the present invention enables the employment of a printing method, facilitating large-area production of a thin film solar cell that can exhibit high photoelectric conversion efficiency. Due to the compound containing a rare earth element and/or other elements, the coating liquid for forming a semiconductor of the present invention changes little over time and can exhibit high storage stability.

The printing method may be, for example, a spin coating method or a roll-to-roll method.

The coating liquid for forming a semiconductor of the present invention includes a compound containing a group 15 element of the periodic table, a sulfur-containing compound and/or a selenium-containing compound, and a compound containing a rare earth element and/or other elements.

The compound containing a group 15 element of the periodic table and the sulfur-containing compound and/or the selenium-containing compound form the sulfide of a group 15 element of the periodic table and/or the selenide of a group 15 element of the periodic table described above in the sulfide and/or selenide semiconductor portion to be formed. The compound containing a group 15 element of the periodic table is preferably a metal-containing compound containing a group 15 metal element of the periodic table. Examples thereof include metal salts and organometallic compounds of group 15 metal elements of the periodic table.

Examples of the metal salts of group 15 metal elements of the periodic table includes chlorides, oxychlorides, nitrates, carbonates, sulfates, ammonium salts, borates, silicates, phosphates, hydroxides, and peroxides of group 15 metal elements of the periodic table. The metal salts of group 15 metal elements of the periodic table include hydrates thereof.

Examples of the organometallic compounds of group 15 elements of the periodic table include salt compounds of group 15 metal elements of the periodic table with carboxylic acids, dicarboxylic acids, oligocarboxylic acids, or polycarboxylic acids. Specific examples thereof include salt compounds of group 15 metal elements of the periodic table with acetic acid, formic acid, propionic acid, octylic acid, stearic acid, oxalic acid, citric acid, or lactic acid.

Specific examples of the compound containing a group 15 element of the periodic table include antimony chloride, antimony acetate, antimony bromide, antimony fluoride, antimony oxyoxide, triethoxyantimony, tripropoxyantimony, bismuth nitrate, bismuth chloride, bismuth hydroxide nitrate, tris(2-methoxyphenyl)bismuth, bismuth carbonate, basic bismuth carbonate, bismuth phosphate, bismuth bromide, triethoxybismuth, triisopropoxyantimony, arsenic iodide, and arsenic triethoxide. These compounds containing a group 15 element of the periodic table may be used alone, or in combination of two or more thereof.

The lower limit of the amount of the compound containing a group 15 element of the periodic table in the coating liquid for forming a semiconductor of the present invention is preferably 0.5% by weight, whereas the upper limit thereof is 70% by weight. If the amount is 0.5% by weight or more, a high-quality sulfide and/or selenide semiconductor portion can be easily formed. If the amount is 70% by weight or less, a stable coating liquid for forming a semiconductor can be easily obtained.

Examples of the sulfur-containing compound include thiourea, derivatives of thiourea, thioacetamide, derivatives of thioacetamide, dithiocarbamates, xanthates, dithiophosphates, thiosulfates, and thiocyanates.

Examples of the derivatives of thiourea include 1-acetyl-2-thiourea, ethylenethiourea, 1,3-diethyl-2-thiourea, 1,3-dimethylthiourea, tetramethylthiourea, N-methylthiourea, and 1-phenyl-2-thiourea. Examples of the dithiocarbamates include sodium dimethyldithiocarbamate, sodium diethyldithiocarbamate, potassium dimethyldithiocarbamate, and potassium diethyldithiocarbamate. Examples of the xanthates include sodium ethyl xanthate, potassium ethyl xanthate, sodium isopropyl xanthate, and potassium isopropyl xanthate. Examples of the thiosulfates include sodium thiosulfate, potassium thiosulfate, and ammonium thiosulfate. Examples of the thiocyanates include sodium thiocyanate, potassium thiocyanate, and ammonium thiocyanate. These sulfur-containing compounds may be used alone, or in combination of two or more thereof.

Examples of the selenium-containing compound include hydrogen selenide, selenium chloride, selenium bromide, selenium iodide, selenophenol, selenourea, selenious acid, and selenoacetamide. These selenium-containing compounds may be used alone, or in combination of two or more thereof.

The amount of the sulfur-containing compound and/or the selenium-containing compound in the coating liquid for forming a semiconductor of the present invention is preferably 1 to 30 times, more preferably 2 to 20 times the number of moles of the compound containing a group 15 element of the periodic table. If the amount is 1 or more times, a sulfide and/or selenide semiconductor having a stoichiometric proportion is easily obtained. If the amount is 30 or less times, the coating liquid for forming a semiconductor can have further improved stability.

The compound containing a group 15 element of the periodic table preferably forms a complex with the sulfur-containing compound and/or the selenium-containing compound. The complex is more preferably formed between the group 15 element of the periodic table and the sulfur-containing compound and/or the selenium-containing compound. The sulfur element in the sulfur-containing compound and the selenium element in the selenium-containing compound have a lone pair of electrons not involved in chemical bonds. These elements thus easily form a coordination bond between an empty electron orbital (d or f orbital) and them.

The formation of such a complex improves the stability of the coating liquid for forming a semiconductor. As a result, a uniform, high-quality sulfide and/or selenide semiconductor portion is formed, improving the production stability. Furthermore, electrical properties and semiconductor properties of the sulfide and/or selenide semiconductor portion are also improved, thus improving performances.

The formation of a complex between the group 15 element of the periodic table and the sulfur-containing compound and/or the selenium-containing compound can be confirmed by measuring an absorption peak due to a bond between the group 15 element of the periodic table and sulfur or a bond between the group 15 element of the periodic table and selenium by the infrared absorption spectrometry. It can also be confirmed by change in the color of the solution.

Examples of the complex formed between the group 15 element of the periodic table and the sulfur-containing compound include a bismuth-thiourea complex, a bismuth-thiosulfuric acid complex, a bismuth-thiocyanic acid complex, an antimony-thiourea complex, an antimony-thiosulfuric acid complex, an antimony-thiocyanic acid complex, an antimony-dithiocarbamic acid complex, and an antimony-xanthogenic acid complex.

Examples of the complex formed between the group 15 element of the periodic table and the selenium-containing compound include an antimony-selenourea complex, an antimony-selenoacetamide complex, and an antimony-dimethylselenourea complex.

The compound containing a rare earth element and/or other elements is the same as that contained in the sulfide and/or selenide semiconductor portion of the thin film solar cell of the present invention described above.

The amount of the compound containing a rare earth element and/or other elements in the coating liquid for forming a semiconductor of the present invention is not limited. The molar ratio (group 15 element of the periodic table:rare earth element and/or other elements) of the group 15 element of the periodic table to the rare earth element and/or other elements is preferably 10:0.1 to 10:5. If the molar ratio of the rare earth element and/or other elements is 0.1 or more, the effects of the addition of the rare earth element and/or other elements can be sufficiently exerted. Furthermore, the thin film solar cell formed using the coating liquid for forming a semiconductor can have high photoelectric conversion efficiency. If the molar ratio of the rare earth element and/or other elements is 5 or less, the sulfide and/or selenide semiconductor portion can maintain its crystalline structure, increasing photoelectric conversion efficiency. The molar ratio (group 15 element of the periodic table:rare earth element and/or other elements) of the group 15 element of the periodic table to the rare earth element and/or other elements is more preferably 10:0.2 to 10:3.5.

The coating liquid for forming a semiconductor of the present invention preferably further contains an organic solvent.

An appropriate selection of the organic solvent can facilitate the formation of the complex mentioned above. The organic solvent is not limited. Examples thereof include methanol, ethanol, N,N-dimethylformamide, dimethylsulfoxide, acetone, dioxane, tetrahydrofuran, isopropanol, n-propanol, chloroform, chlorobenzene, pyridine, and toluene. These organic solvents may be used alone, or in combination of two or more thereof. In particular, methanol, ethanol, acetone, and N,N-dimethylformamide are preferred, and N,N-dimethylformamide is more preferred as it contributes to the formation of a sulfide and/or selenide semiconductor portion with even better electrical properties and semiconductor properties.

The coating liquid for forming a semiconductor of the present invention may further contain a non-organic solvent component such as water to the extent that it does not impair the effects of the present invention.

The present invention also encompasses a semiconductor thin film containing a sulfide of a group 15 element of the periodic table and/or a selenide of a group 15 element of the periodic table and a compound containing a rare earth element and/or other elements.

The sulfide of a group 15 element of the periodic table and/or the selenide of a group 15 element of the periodic table and the compound containing a rare earth element and/or other elements are the same as those contained in the sulfide and/or selenide semiconductor portion of the thin film solar cell of the present invention described above. The semiconductor thin film of the present invention is useful as a photoelectric conversion material for solar cells as it contains the compound containing a rare earth element and/or other elements in addition to the sulfide of a group 15 element of the periodic table and/or the selenide of a group 15 element of the periodic table. The semiconductor thin film of the present invention is also useful as a photocatalyst material, a photoconductive material, or other materials.

### Advantageous Effects of Invention

The present invention can provide a thin film solar cell that can exhibit high photoelectric conversion efficiency. The present invention can also provide a semiconductor thin film intended to be used in the thin film solar cell and a coating liquid for forming a semiconductor which can facilitate large-area production of the thin film solar cell and can improve production stability.

### BRIEF DESCRIPTION OF DRAWINGS

FIG. 1 is a cross-sectional view schematically showing an exemplary embodiment of the thin film solar cell of the present invention which includes a photoelectric conversion layer that is a laminate including a sulfide and/or selenide semiconductor portion in the form of a thin film and an organic semiconductor portion in the form of a thin film.

FIG. 2 is a cross-sectional view schematically showing an exemplary embodiment of the thin film solar cell of the present invention which includes a photoelectric conversion layer that is a composite film including a composite of a sulfide and/or selenide semiconductor portion and an organic semiconductor portion.

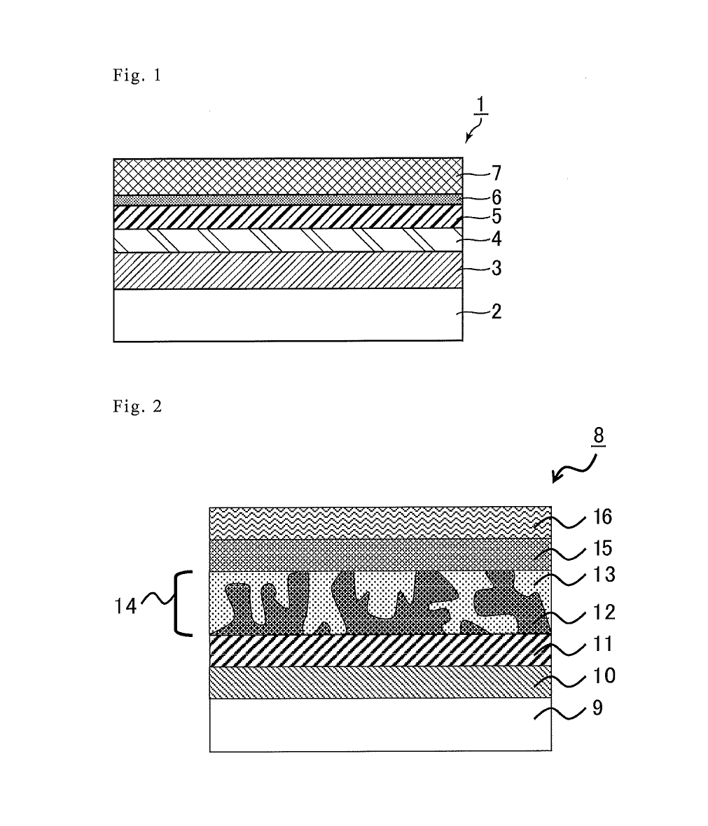

### DESCRIPTION OF EMBODIMENTS

The following will describe the present invention in more detail with reference to examples. The present invention should not be limited to these examples.

### Example 1

### Preparation of Coating Liquid for Forming Semiconductor

An amount of 20 parts by weight of antimony (III) chloride was added to 100 parts by weight of N,N-dimethylformamide. The mixture was then stirred to achieve dissolution. Separately, 20 parts by weight of thiourea (CS(NH₂)₂) was added to 100 parts by weight of N,N-dimethylformamide. The mixture was then stirred to achieve dissolution. An amount of 40 parts by weight of the solution of thiourea in N,N-dimethylformamide was gradually added to 50 parts by weight of the solution of antimony chloride in N,N-dimethylformamide with stirring. During the addition, the solution, which was clear colorless before mixing, turned into clear yellow. The formation of a complex was confirmed by measuring an infrared absorption spectrum of the solution. After the addition was completed, the mixed solution was stirred for another 30 minutes. Thus, a stock solution containing antimony chloride and thiourea was prepared.

An amount of 20 parts by weight of yttrium nitrate n-hydrate Y(NO₃)₃nH₂O was added to 100 parts by weight of N,N-dimethylformamide. The mixture was then stirred to achieve dissolution. After the addition was completed, the mixture was stirred for another 30 minutes. Thus, a stock solution containing yttrium nitrate was prepared.

An amount of 5 parts by weight of the stock solution containing yttrium nitrate was added to 95 parts by weight of the stock solution containing antimony chloride and thiourea. The mixture was stirred to achieve dissolution. Thus, a coating liquid for forming a semiconductor was prepared. The obtained coating liquid for forming a semiconductor had a molar ratio antimony:sulfur:yttrium of 10:24:0.5.

### (Preparation of Thin Film Solar Cell Using Porous Electron Transport Layer)

An aqueous solution of a titanium hydroxycarboxylate compound was applied to a FTO glass substrate by a spin coating method at 3000 rpm. This was followed by burning in the air at 550° C. for 10 minutes. A paste containing TiO₂ nanoparticles (particle size: 30 nm) was applied to the obtained film. This was followed by burning in the air at 550° C. for 10 minutes. Thus, a porous electron transport layer was formed.

The coating liquid for forming a semiconductor was applied to the obtained porous electron transport layer by a spin coating method at 1500 rpm. Thereafter, the sample was put in a vacuum furnace and burnt at 260° C. for 10 minutes while a vacuum was drawn, whereby a sulfide semiconductor thin film (sulfide semiconductor portion in the form of a thin film) was obtained (thickness: 120 nm, band gap: 1.7 eV). The sulfide semiconductor thin film taken out of the vacuum furnace was black. The thickness of the sulfide semiconductor thin film was the average film thickness measured with a film thickness meter (KLA-TENCOR, P-16+). The band gap of the sulfide semiconductor thin film was estimated from am absorption spectrum measured with a spectrophotometer (U-4100, available from Hitachi High-Technologies Corporation). Measurement using an ICP emission spectrometer (ICPS-7500, available from Shimadzu) on the sulfide semiconductor thin film showed that the antimony sulfide content and the yttrium nitrate content were 92 mol % and 8 mol %, respectively, in 100 mol % of the total amount of antimony and yttrium nitrate.

A film of poly(3-hexylthiophene) (P3HT) with a thickness of 100 nm as an organic semiconductor thin film (organic semiconductor portion in the form of a thin film) was formed on the obtained sulfide semiconductor thin film by a spin coating method. Thereafter, a film of poly(3,4-ethylene dioxythiophene):poly(styrene sulfonate) (PEDOT:PSS) with a thickness of 100 nm as a hole-transparent layer was formed on the organic semiconductor thin film by a spin coating method. Then, a gold electrode with a thickness of 80 nm was formed on the hole transport layer by a vacuum evaporation method. Thus, a thin film solar cell was prepared.

### Examples 2 to 27

### Comparative Examples 1 to 15

A coating liquid for forming a semiconductor and a thin film solar cell were prepared in the same manner as in Example 1 except that the compound containing a group 15 element of the periodic table, the sulfur-containing compound or selenium-containing compound, and the compound containing a rare earth element and/or other elements (or other compounds) and the amounts thereof were changed as shown in Tables 1 and 2.

### Examples 28 and 29

An aqueous solution of a titanium hydroxycarboxylate compound was applied to a FTO glass substrate by a spin coating method at 1500 rpm. This was followed by burning in the air at 550° C. for 10 minutes. Thus, a flat electron transport layer with an arithmetic average roughness Ra of about 1 nm was formed.

A thin film solar cell was prepared in the same manner as in Examples 8 and 15 except that the coating liquid for forming a semiconductor was applied to the obtained flat electron transport layer to form a sulfide semiconductor thin film.

### Examples 30 and 31

### Preparation of Thin Film Solar Cell

A thin film solar cell was prepared in the same manner as in Example 1 except that the chemical deposition method described below was used instead of using the coating liquid for forming a semiconductor.

### [Chemical Deposition Method]

An amount of 72.5 mL of ion-exchanged water (water temperature: 5° C. to 10° C.) was added to a 25 mL of 1 M aqueous solution of Na₂S₂O₃ (solution temperature: 5° C. to 10° C.), and further 2.5 mL of a 1 M solution of SbCl₃ in acetone was added thereto. The resulting solution was stirred for one minute. Thereafter, a porous titanium oxide film provided with a blocking layer was immersed in the solution, and deposition was performed in a refrigerator (temperature: 5° C. to 10° C.) for three hours. The obtained sample was taken out of the solution and then washed with ion-exchanged water so that excess washed away. The sample was put in a vacuum furnace and burnt at 260° C. for 10 minutes while drawing a vacuum. In this manner, a sulfide semiconductor thin film (sulfide semiconductor portion in the form of a thin film) was obtained.

In Example 30, titanium was subsequently added at 4 mol % in the same manner as described above except that 2.5 mL of a 0.05 M solution of titanium chloride in acetone was used instead of 2.5 mL of 1 M solution of SbCl₃ in acetone, and that the sample provided with the sulfide semiconductor thin film was immersed. In Example 31, zinc was added at 4 mol % in the same manner as described above except that 2.5 mL of a 0.05 M solution of zinc chloride in acetone was used instead of 2.5 mL of a 1 M solution of SbCl₃ in acetone, and that the sample provided with the sulfide semiconductor thin film was immersed.

### Examples 32 and 33

An aqueous solution of a titanium hydroxycarboxylate compound was applied to a FTO glass substrate by a spin coating method at 1500 rpm. This was followed by burning in the air at 550° C. for 10 minutes. Thus, a flat electron transport layer was formed.

A thin film solar cell was prepared in the same manner as in Examples 30 and 31 except that the obtained flat electron transport layer was used.

### Example 34

An aqueous solution of a titanium hydroxycarboxylate compound was applied to a FTO glass substrate by a spin coating method at 1500 rpm. This was followed by burning in the air at 550° C. for 10 minutes. Thus, a flat electron transport layer was formed.

A thin film solar cell was prepared in the same manner as in Examples 1 except that antimony sulfide and zinc were co-evaporated onto the obtained flat electron transport layer by a co-evaporation method to form a semiconductor thin film.

### <Evaluation>

The thin film solar cells obtained in the examples and comparative examples were subjected to the evaluations below. The coating liquids for forming a semiconductor prepared in the examples and comparative examples were subjected to the evaluations below.

The results are shown in Tables 1 and 2.

### (1) Surface Roughness of Semiconductor Thin Film

The surface profile of the obtained sulfide semiconductor thin film was measured with DIMENSION ICON AFM available from Bruker. The arithmetic average roughness Ra of the film surfaces was calculated by the method in accordance with JIS B 0601-2001. The surface roughness of the sulfide semiconductor thin film was evaluated according to the following criteria.

x (poor): The arithmetic average roughness Ra of the surfaces was 0 nm or more and less than 5 nm.
Δ (acceptable): The arithmetic average roughness Ra of the surfaces was 5 nm or more and less than 10 nm.
∘ (good): The arithmetic average roughness Ra of the surfaces was 10 nm or more and less than 20 nm.
∘∘ (excellent): The arithmetic average roughness Ra of the surfaces was 20 nm or more.

### (2) Evaluation of Relative Conversion Efficiency of Thin Film Solar Cell

A power source (Model 236, available from Keithley Instruments Inc.) was connected between the electrodes of each of the thin film solar cells obtained in the examples and comparative examples. The photoelectric conversion efficiency of each thin film solar cell was measured using a solar simulator (available from Yamashita Denso Corporation) at an intensity of 100 mW/cm².

The photoelectric conversion efficiencies of the thin film solar cells obtained in Examples 1 to 26, 28 to 34 and Comparative Examples 2 to 14 were standardized based on the photoelectric conversion efficiency of the thin film solar cell obtained in Comparative Example 1 regarded as 1.0 (in the case of antimony sulfide thin film). The photoelectric conversion efficiency of the thin film solar cell obtained in Example 27 was standardized based on the photoelectric conversion efficiency of the thin film solar cell obtained in Comparative Example 15 regarded as 1.0 (in the case of antimony selenide thin film).

### (3) Evaluation of Production Stability of Thin Film Solar Cell

Four evaluation cells were prepared for each of the thin film solar cells of the examples and comparative examples in the same manner as the thin film solar cells of the examples and comparative examples. The relative photoelectric conversion efficiency of each of the four evaluation cells was measured in the same manner as in the evaluation (2). The production stability was evaluated according to the following criteria.

Δ (acceptable): The difference between the maximum and minimum relative photoelectric conversion efficiencies was more than 20% of the maximum relative photoelectric conversion efficiency.
∘ (good): The difference between the maximum and minimum relative photoelectric conversion efficiencies was 20% or less of the maximum relative photoelectric conversion efficiency.

### (4) Evaluation of Film Thickness Dependence of Conversion Efficiency of Thin Film Solar Cell

For each of Examples 28, 29, 32, 33, and 34, where flat electron transport layers were used, an evaluation cell with a 120 nm-thick sulfide semiconductor thin film and an evaluation cell with a 150 nm-thick sulfide semiconductor thin film were prepared in the same manner as in these examples. The relative conversion efficiency of the evaluation cells were measured in the same manner as in the evaluation (2). The relative conversion efficiency of the cell with a 150 nm-thick sulfide semiconductor thin film was standardized based on that of the cell with a 120 nm-thick sulfide semiconductor thin film regarded as 1.0. The film thickness dependence was evaluated according to the following criteria.

∘∘ (excellent): The standardized value was more than 0.8.
∘ (good): The standardized value was more than 0.5 and 0.8 or less.
Δ (acceptable): The standardized value was 0.5 or less.

### (5) Evaluation of Storage Stability of Coating Liquid for Forming Semiconductor

A thin film solar cell was prepared in the same manner as in Comparative Example 1 using a coating liquid for forming a semiconductor that had been stored in the air at 25° C. for one day. The photoelectric conversion efficiency of the thin film solar cell was standardized relative to the photoelectric conversion efficiency of a thin film solar cell prepared in the same manner as in Comparative Example 1 using a freshly prepared coating liquid for forming a semiconductor regarded as 1.0. The resulting value was taken as E1. Separately, thin film solar cells were prepared in the same manner as in Examples 1 to 26 and 28 and 29 using a coating liquid for forming a semiconductor that had been stored in the air at 25° C. for one day. The photoelectric conversion efficiencies of these thin film solar cells were standardized relative to the photoelectric conversion efficiencies of thin film solar cells prepared in the same manner as in Examples 1 to 26 and 28 and 29 using a freshly prepared coating liquid for forming a semiconductor regarded as 1.0. The resulting values were taken as E3.

A thin film solar cell was prepared in the same manner as in Comparative Example 15 using a coating liquid for forming a semiconductor that had been stored in the air at 25° C. for one day. The photoelectric conversion efficiency of this thin film solar cell was standardized relative to the photoelectric conversion efficiency of a thin film solar cell prepared in the same manner as in Comparative Example 15 using a freshly prepared coating liquid for forming a semiconductor regarded as 1.0. The resulting value was taken as E2. Separately, a thin film solar cell was prepared in the same manner as in Example 27 using a coating liquid for forming a semiconductor that had been stored in the air at 25° C. for one day. The photoelectric conversion efficiency of the thin film solar cell was standardized relative to the photoelectric conversion efficiency of a thin film solar cell prepared in the same manner as in Example 27 using a freshly prepared coating liquid for forming a semiconductor regarded as 1.0. The resulting value was taken as E4.

The photoelectric conversion efficiency was measured with a solar simulator (available from Yamashita Denso Corporation) at an intensity of 100 mW/cm². In the measurement, a power source (Model 236, available from Keithley Instruments Inc.) was connected between the electrodes of the thin film solar cell.

The storage stability was evaluated according to the following criteria using the obtained values.

∘ (good): E3/E1 was more than 1.01 or E4/E2 was more than 1.01

TABLE 1

| | Coating liquid for forming semiconductor | | | | | | | | | | Thin film solar cell | | | | | | | |
|---|---|---|---|---|---|---|---|---|---|---|---|---|---|---|---|---|---|---|
| | Compound | | | | | | | | | | | Semiconductor film | | | | | | |
| | containing | | Sulfur-containing | | Compound containing rare | | | | | | | Sulfide of | Compound | | | | | |
| | group 15 | | compound and/or | | earth element/Zn/Ti | | | | | | | group 15 | containing | | | | | |
| | element of the | | selenium-containing | | | | Rare | | | | | element of | rare | | | | | |
| | periodic table | | compound | | | | earth | | | | Elec- | the periodic | earth | | | | | |
| | | Group | | Sulfur | | | ele- | | | | tron | table and/or | element | | | | | Coating |
| | | 15 | | and/or | | | ment/ | | | | trans- | selenide of | and/or | Thin film solar cell evaluation | | | | liquid |
| | | element | | selenium | | | Zn/Ti | Other compounds | | | port | group 15 element | other | Surface | Relative | Produc- | Film | evaluation |
| | Com- | molar | Com- | molar | Ele- | | molar | Ele- | Com- | Molar | layer | of the periodic | elements | rough- | conversion | tion | thickness | Storage |
| | pound | ratio | pound | ratio | ment | Compound | ratio | ment | pound | ratio | Shape | table (mol %) | (mol %) | ness | efficiency | stability | dependence | stability |
| Example 1 | Antimony | 10 | Thiourea | 24 | Y | Yttrium nitrate | 0.5 | | | | Porous | 92 | 8 | ◯◯ | 1.38 | ◯ | Not | ◯ |
| | chloride | | | | | n-hydrate | | | | | | | | | | | measured | |
| Example 2 | | 10 | | | La | Lanthanum nitrate | 1 | | | | | 87 | 13 | | 1.67 | | | |
| | | | | | | hexahydrate | | | | | | | | | | | | |
| Example 3 | | 10 | | | Ce | Cerium nitrate | 1 | | | | | 91 | 9 | | 1.18 | | | |
| | | | | | | hexahydrate | | | | | | | | | | | | |
| Example 4 | | 10 | | | Nd | Neodymium nitrate | 1 | | | | | 85 | 15 | | 1.45 | | | |
| | | | | | | hexahydrate | | | | | | | | | | | | |
| Example 5 | | 10 | | | Sm | Samarium nitrate | 1 | | | | | 84 | 16 | | 1.30 | | | |
| | | | | | | n-hydrate | | | | | | | | | | | | |
| Example 6 | | 10 | | | Eu | Europium nitrate | 1 | | | | | 89 | 11 | | 1.02 | | | |
| | | | | | | n-hydrate | | | | | | | | | | | | |
| Example 7 | | 10 | | | Gd | Gadolinium nitrate | 1 | | | | | 86 | 14 | | 1.15 | | | |
| | | | | | | n-hydrate | | | | | | | | | | | | |
| Example 8 | | 10 | | | Tb | Terbium chloride | 1 | | | | | 87 | 13 | | 1.41 | | | |
| | | | | | | hexahydrate | | | | | | | | | | | | |
| Example 9 | | 10 | | | Dy | Dysprosium nitrate | 2.5 | | | | | 76 | 24 | | 1.44 | | | |
| | | | | | | pantahydrate | | | | | | | | | | | | |
| Example 10 | | 10 | | | Ho | Holmium nitrate | 0.5 | | | | | 95 | 5 | | 1.07 | | | |
| | | | | | | n-hydrate | | | | | | | | | | | | |
| Example 11 | | 10 | | | Er | Erbium nitrate | 1 | | | | | 87 | 13 | | 1.30 | | | |
| | | | | | | n-hydrate | | | | | | | | | | | | |
| Example 12 | | 10 | | | Tm | Thulium nitrate | 0.5 | | | | | 91 | 9 | | 1.12 | | | |
| | | | | | | pantahydrate | | | | | | | | | | | | |
| Example 13 | | 10 | | | Yb | Ytterbium chloride | 0.5 | | | | | 93 | 7 | | 1.17 | | | |
| | | | | | | hexahydrate | | | | | | | | | | | | |
| Example 14 | | 10 | | | Lu | Lutetium nitrate | 0.5 | | | | | 90 | 10 | | 1.52 | | | |
| | | | | | | n-hydrate | | | | | | | | | | | | |
| Example 15 | | 10 | | | Zn | Zinc chloride | 0.5 | | | | | 92 | 8 | | 1.48 | | | |
| Example 16 | | 10 | | | Sc | Scandium chloride | 0.5 | | | | | 94 | 6 | | 1.50 | | | |
| | | | | | | hexahydrate | | | | | | | | | | | | |
| Example 17 | | 10 | | | Ti | Titanium | 1 | | | | | Not | Not | | 1.32 | | | |
| | | | | | | isopropoxide | | | | | | measured | measured | | | | | |
| Example 18 | | 10 | | | La | Lanthanum nitrate | 0.1 | | | | | 99 | 1 | | 1.03 | | | |
| | | | | | | hexahydrate | | | | | | | | | | | | |
| Example 19 | | 10 | | | La | | 0.5 | | | | | 92 | 8 | | 1.43 | | | |
| Example 20 | | 10 | | | La | | 1.5 | | | | | 80 | 20 | | 1.39 | | | |
| Example 21 | | 10 | | | La | | 2.5 | | | | | 74 | 26 | | 1.09 | | | |
| Example 22 | | 10 | | | La | | 5 | | | | | 67 | 33 | | 1.02 | | | |
| Example 23 | Antimony | 10 | | | La | | 1 | | | | | 84 | 16 | | 1.49 | | | |
| | bromide | | | | | | | | | | | | | | | | | |
| Example 24 | Antimony | 10 | | | La | | 1 | | | | | 89 | 11 | | 1.22 | | | |
| | fluoride | | | | | | | | | | | | | | | | | |
| Example 25 | Antimony | 10 | Thioaceto- | | La | | 1 | | | | | 86 | 14 | | 1.16 | | | |
| | chloride | | amide | | | | | | | | | | | | | | | |
| Example 26 | | 10 | Dithiobiuret | | La | | 0.5 | | | | | 92 | 8 | | 1.08 | | | |
| Example 27 | | 10 | Selenourea | | Zn | Zinc chloride | 0.5 | | | | | 91 | 9 | | 1.18 | | | |
| Example 28 | | 10 | Thiourea | | Tb | Terbium chloride | 1 | | | | Flat | 88 | 12 | ◯ | 1.32 | | ◯◯ | |
| | | | | | | hexahydrate | | | | | | | | | | | | |
| Example 29 | | 10 | | | Zn | Znc chloride | 1 | | | | | 84 | 16 | | 1.45 | | | |

| | | | | | | | | | | | | |
|---|---|---|---|---|---|---|---|---|---|---|---|---|
| Example 30 | Chemical vapor deposition | Ti | Titanium chloride | 4 | Porous | 95 | 5 | ◯◯ | 1.40 | Δ | Not | Not |
| Example 31 | method (antimony sulfide) | Zn | Znc chloride | 4 | | 95 | 5 | | 1.25 | | measured | measured |
| Example 32 | Chemical vapor deposition | Ti | Titanium chloride | 4 | Flat | 98 | 2 | Δ | 1.10 | | ◯ | |
| Example 33 | method (antimony sulfide) | Zn | Eric chloride | 4 | | 96 | 4 | | 1.13 | | | |
| Example 34 | Evaporation (antimony sulfide) | Zn | — | — | | 95 | 5 | X | 1.05 | ◯ | Δ | |

| | Coating liquid for forming semiconductor | | | | | | | | | | | | | | | | | |
|---|---|---|---|---|---|---|---|---|---|---|---|---|---|---|---|---|---|---|
| | | | Sulfur- | | | | | | | | Thin film solar cell | | | | | | | |
| | Compound | | containing | | | | | | | | | Semiconductor film | | | | | | |
| | containing | | compound | | Compound | | | | | | | Sulfide of | | | | | | |
| | group 15 | | and/or | | containing rare earth | | | | | | | group 15 | Compound | | | | | |
| | element of | | selenium- | | element/Zn/Ti | | | | | | | element of | containing | | | | | |
| | the periodic | | containing | | | | Rare | | | | | the periodic | rare | Thin film solar cell evaluation | | | | |
| | table | | compound | | | | earth | | | | Elec- | table and/or | earth | | Rela- | | | |
| | | Group | | Sulfur | | | element/ | | | | tron | selenide of | element | | tive | Pro- | Film | Coating |
| | | 15 | | and/or | | | Zn/ | | | | trans- | group 15 | and/or | Sur- | conver- | duc- | thick- | liquid |
| | | element | | selenium | | | Ti | Other compounds | | | port | element of the | other | face | sion | tion | ness | evaluation |
| | | molar | | molar | | | molar | | | Molar | layer | periodic table | elements | rough- | effi- | stabil- | depen- | Storage |
| | Compound | ratio | Compound | ratio | Element | Compound | ratio | Element | Compound | ratio | Shape | (mol %) | (mol %) | ness | ciency | ity | dence | stability |
| Comparative | Antimony | 10 | Thiourea | 24 | — | Not | — | — | — | — | Porous | 100 | 0 | ◯◯ | 1.00 | ◯ | ◯ | — |
| Example 1 | chloride | | | | | added | | | | | | | | | | | | |
| Comparative | | 10 | | 24 | | | | Fe | Iron | 1 | | Not | Not | | 0.46 | ◯ | Not | Not |
| Example 2 | | | | | | | | | chloride | | | measured | measured | | | | measured | measured |
| Comparative | | 10 | | 24 | | | | Co | Cobalt | 1 | | Not | Not | | 0.01 | ◯ | Not | Not |
| Example 3 | | | | | | | | | chloride | | | measured | measured | | | | measured | measured |
| Comparative | | 10 | | 24 | | | | Ni | Nickel | 1 | | Not | Not | | 0.01 | ◯ | Not | Not |
| Example 4 | | | | | | | | | acetate | | | measured | measured | | | | measured | measured |
| Comparative | | 10 | | 24 | | | | Ge | Germanium | 1 | | Not | Not | | 0.02 | ◯ | Not | Not |
| Example 5 | | | | | | | | | iodide | | | measured | measured | | | | measured | measured |
| Comparative | | 10 | | 24 | | | | Mo | Molybdenum | 1 | | Not | Not | | 0.01 | ◯ | Not | Not |
| Example 6 | | | | | | | | | chloride | | | measured | measured | | | | measured | measured |
| Comparative | | 10 | | 24 | | | | Ru | Ruthenium | 1 | | Not | Not | | 0.01 | ◯ | Not | Not |
| Example 7 | | | | | | | | | chloride | | | measured | measured | | | | measured | measured |
| Comparative | | 10 | | 24 | | | | In | Indium | 1 | | Not | Not | | 0.58 | ◯ | Not | Not |
| Example 8 | | | | | | | | | chloride | | | measured | measured | | | | measured | measured |
| Comparative | | 10 | | 24 | | | | W | Tungsten | 1 | | Not | Not | | 024 | ◯ | Not | Not |
| Example 9 | | | | | | | | | chloride | | | measured | measured | | | | measured | measured |
| Comparative | | 10 | | 24 | | | | Os | Osmium | 1 | | Not | Not | | 0.00 | ◯ | Not | Not |
| Example 10 | | | | | | | | | chloride | | | measured | measured | | | | measured | measured |
| Comparative | | 10 | | 24 | | | | Cu | Copper | 1 | | Not | Not | | 0.32 | ◯ | Not | Not |
| Example 11 | | | | | | | | | chloride | | | measured | measured | | | | measured | measured |
| Comparative | | 10 | | 24 | | | | Mg | Magnesium | 1 | | Not | Not | | 0.60 | ◯ | Not | Not |
| Example 12 | | | | | | | | | chloride | | | measured | measured | | | | measured | measured |
| Comparative | | 10 | | 24 | | | | Ga | Gallium | 1 | | Not | Not | | 0.03 | ◯ | Not | Not |
| Example 13 | | | | | | | | | chloride | | | measured | measured | | | | measured | measured |
| Comparative | | 10 | | 24 | | | | Pb | Lead | 1 | | Not | Not | | 0.35 | ◯ | Not | Not |
| Example 14 | | | | | | | | | iodide | | | measured | measured | | | | measured | measured |
| Comparative | Antimony | 10 | Selenourea | 24 | — | Not | — | — | — | — | | 100 | 0 | | 1.00 | ◯ | ◯ | — |
| Example 15 | chloride | | | | | added | | | | | | | | | | | | |

### INDUSTRIAL APPLICABILITY

The present invention can provide a thin film solar cell which can exhibit high photoelectric conversion efficiency. The present invention can also provide a semiconductor thin film intended to be used in the thin film solar cell and to a coating liquid for forming a semiconductor which can facilitate large-area production of the thin film solar cell and can improve production stability.

### REFERENCE SIGNS LIST

1 Thin film solar cell
2 Substrate
3 Electrode (anode)
4 Organic semiconductor portion in the form of a thin film
5 Sulfide and/or selenide semiconductor portion in the form of
a thin film
6 Electron transport layer
7 Transparent electrode (cathode)
8 Thin film solar cell
9 Substrate
10 Electrode (anode)
11 Hole transport layer
12 Organic semiconductor portion
13 Sulfide and/or selenide semiconductor portion
14 Composite film
15 Electron transport layer
16 Transparent electrode (cathode)

1. A thin film solar cell comprising
a photoelectric conversion layer,
the photoelectric conversion layer including a portion that includes a sulfide of a group 15 element of the periodic table and/or a selenide of a group 15 element of the periodic table and a compound containing at least one element selected from the group consisting of a rare earth element, titanium, and zinc.

2. The thin film solar cell according to claim 1,
wherein the photoelectric conversion layer further includes a portion that includes an organic semiconductor.

3. The thin film solar cell according to claim 1,
wherein surfaces of the photoelectric conversion layer each have an arithmetic average roughness Ra measured in accordance with JIS B 0601-2001 of 5 nm or more.

4. The thin film solar cell according to claim 1,
wherein the photoelectric conversion layer is disposed between a pair of electrodes.

5. A semiconductor thin film comprising
a sulfide of a group 15 element of the periodic table and/or a selenide of a group 15 element of the periodic table, and
a compound containing at least one selected from the group consisting of a rare earth element, titanium, and zinc.

6. A coating liquid for forming a semiconductor, the coating liquid comprising
a compound containing a group 15 element of the periodic table,
a sulfur-containing compound and/or a selenium-containing compound, and
a compound containing at least one element selected from the group consisting of a rare earth element, titanium, and zinc.

7. The coating liquid for forming a semiconductor according to claim 6,
wherein the compound containing a group 15 element of the periodic table forms a complex with the sulfur-containing compound and/or the selenium-containing compound.

8. The coating liquid for forming a semiconductor according to claim 6,
wherein the coating liquid further contains an organic solvent.

9. The thin film solar cell according to claim 2,
wherein surfaces of the photoelectric conversion layer each have an arithmetic average roughness Ra measured in accordance with JIS B 0601-2001 of 5 nm or more.

10. The thin film solar cell according to claim 2,
wherein the photoelectric conversion layer is disposed between a pair of electrodes.

11. The thin film solar cell according to claim 3,
wherein the photoelectric conversion layer is disposed between a pair of electrodes.

12. The thin film solar cell according to claim 9,
wherein the photoelectric conversion layer is disposed between a pair of electrodes.

13. The coating liquid for forming a semiconductor according to claim 7,
wherein the coating liquid further contains an organic solvent.
